(19) United States
(12) Patent Application Publication
(10) Pub. No.: US 2023/0110159 A1
(43) Pub. Date: Apr. 13, 2023

(54) LIGHT EMITTING DEVICE AND METHOD OF FABRICATING THEREOF

(71) Applicant: AUO Corporation, HSIN-CHU (TW)

(72) Inventors: Chun-Hsiang CHAN, HSIN-CHU (TW); Seok-Lyul LEE, HSIN-CHU (TW); Shih-Chi FAN JIANG, HSIN-CHU (TW); Li-Kai CHIA, HSIN-CHU (TW)

(21) Appl. No.: 17/899,890

(22) Filed: Aug. 31, 2022

(30) Foreign Application Priority Data
Oct. 8, 2021 (TW) 110137602

(51) Int. Cl. H01L 33/60; H01L 25/075; H01L 33/50; H01L 33/58; H01L 33/62

(52) U.S. Cl. CPC H01L 33/60; H01L 25/0753; H01L 33/50; H01L 33/58; H01L 33/62; H01L 2933/0091; H01L 2933/0058; H01L 2933/0066

(57) ABSTRACT

A light emitting device includes a substrate, multiple light emitting diodes disposed on the substrate and a light-reflecting resist. The light emitting diode has a first electrode and a second electrode, both of which are disposed on a first surface of the light emitting diode facing the substrate. The light-reflecting resist is disposed between the light emitting diodes and directly contacts a side surface of the light emitting diode. At least a portion of the light-reflecting resist is disposed between the first electrode and the second electrode.

### CROSS-REFERENCE TO RELATED APPLICATION

This application claims priority to Taiwan Application Serial Number 110137602, filed Oct. 8th, 2021, which is herein incorporated by reference in its entirety.

### BACKGROUND

### Field of Invention

The present disclosure relates to a light emitting device and a method of fabricating thereof, and particularly to a light emitting device applied in a display and a method of fabricating thereof.

### Description of Related Art

The light emitting diode (LED) is widely applied in illuminations and displays for its advantages including small size, low power consumption, long life time, luminescence, and so on. As the LED is applied in the display, the scaling-down of the LED and the reduced pitch can enhance the resolution of the display.

### SUMMARY

An aspect of the present disclosure provides a light emitting device including a substrate, multiple light emitting diodes disposed on the substrate and a light-reflecting resist. The light emitting diode has a first electrode and a second electrode, both of which are disposed on a first surface of the light emitting diode facing the substrate. The light-reflecting resist is disposed between the light emitting diodes and directly contacts a side surface of the light emitting diode. At least a portion of the light-reflecting resist is disposed between the first electrode and the second electrode.

An aspect of the present disclosure provides a method of fabricating a light emitting device including disposing multiple light emitting diodes on a substrate, where each light emitting diode includes a first electrode and a second electrode. The method of fabricating the light emitting device further includes disposing a resist material between the adjacent light emitting diodes and between the first electrode and the second electrode after disposing the multiple light emitting diodes on the substrate. The resist material directly contacts a side surface of the light emitting diodes.

It is to be understood that both the foregoing general description and the following detailed description are by examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a light emitting device in accordance with some embodiments.

FIG. 2 is an enlarged cross-sectional view of a portion of the light emitting device shown in FIG. 1 in accordance with some embodiments.

FIG. 3A to FIG. 3D are cross-sectional views of a light emitting device in various process stages in accordance with some embodiments.

FIG. 4 to FIG. 9 are cross-sectional views of a light emitting device in accordance with some other embodiments.

FIG. 10 is a cross-sectional view of a light emitting device with a color conversion layer in accordance with some embodiments.

FIG. 11 is a cross-sectional view of a light emitting device with a color conversion layer in accordance with some other embodiments.

### DETAILED DESCRIPTION

The following disclosure provides many different embodiments, or examples, for implementing different features of the disclosure. For illustration clarity, many details of practice are explained in the following descriptions. However, it should be understood that these details of practice do not intend to limit the present disclosure. That is, these details of practice are not necessary in parts of embodiments of the present disclosure. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The use of ordinals such as first, second and third does not necessarily imply a ranked sense of order, but rather may only distinguish between multiple instances of an act or structure.

In some embodiments, the terms “about” and “substantially” can refer to a percentage of the values as interpreted by those skilled in relevant art(s) in light of the teachings herein. The terms “about” and “substantially” can indicate a value of a given quantity that varies within an acceptable deviation of the value. These values are merely examples and are not intended to be limiting.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The light emitting diode (LED) is widely applied in illuminations and displays for its advantages including small size, low power consumption, long life time, luminescence, and so on. As the LED is applied in the display, the scaling-down of the LED and the reduced pitch can enhance the resolution of the display. With the resolution of the display increased (e.g., the resolution is higher than 250 pixels per inch (PPI)), the scaling-down of the LED may be subject to lateral light guiding, and the reduced pitch may increase the difficulty of the manufacturing process and decrease the control of the lateral light guiding. For example, it is not easy to form a blocking structure (e.g., the barrier or bank) against the lateral light guiding in a confined area. The present disclosure provides a light emitting device and a method of fabricating the same in order to increase the light efficiency and the reliability of the light emitting device.

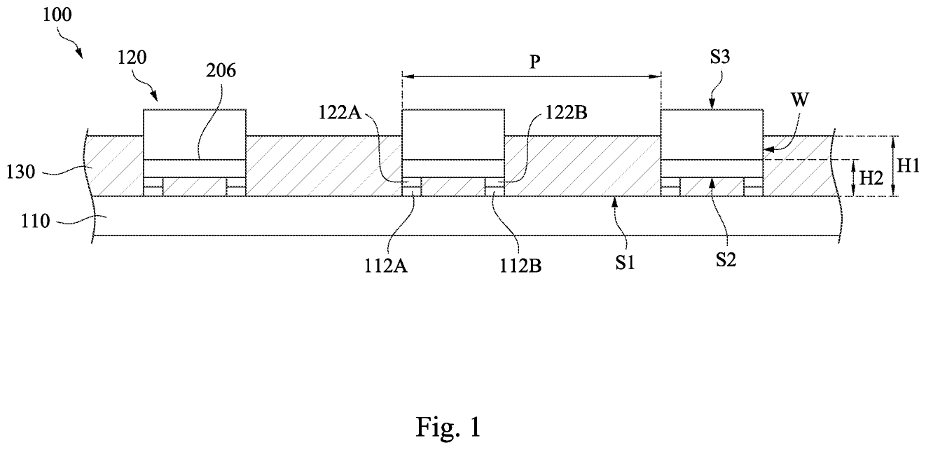

Referring to FIG. 1, FIG. 1 is a cross-sectional view of a light emitting device 100 in accordance with some embodiments. The light emitting device 100 includes a substrate 110, multiple light emitting diodes (LED) 120 disposed on the substrate 110, and a light-reflecting resist 130 disposed around the LED 120.

The substrate 110 can be a glass substrate, a silicon substrate, a thin film transistor (TFT) substrate, or other suitable substrates. In some embodiments, the substrate 110 includes a contact 112A and a contact 1128. The contact 112A and the contact 1128 are disposed on a first surface S1 of the substrate 110 and bonded to an electrode 122A and an electrode 1228 of the LED 120 respectively. The electrode 122A and the electrode 122B of the LED 120 may be disposed on a second surface S2 of the LED 120. The second surface S2 of the LED 120 is faced towards the first surface S1 of the substrate 110.

The contact 112A can include metal, such as Au, Sn, Sn/Ag/Cu alloy, or Sn alloy, but the present disclosure is not limited thereto. The material of the contact 1128 can substantially be the same as the material of the contact 112A. Further, the material of the electrode 122A and the electrode 1228 can be selected from the similar material of the contact 112A or the contact 1128.

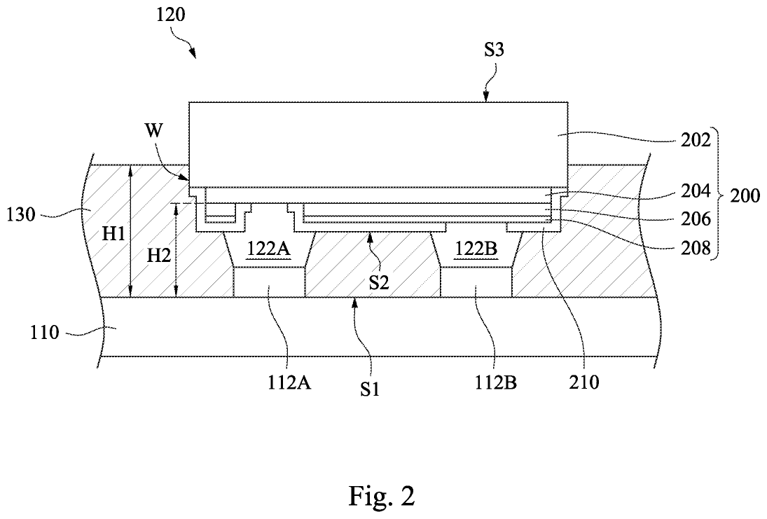

Referring to FIG. 2, FIG. 2 is an enlarged cross-sectional view of a portion of the light emitting device 100 shown in FIG. 1 in accordance with some embodiments. In the detailed view of the single LED 120 shown in FIG. 2, the LED includes a semiconductor stack 200. The semiconductor stack 200 may include an undoped semiconductor layer 202, an N-type doped semiconductor layer 204, a light-emitting layer 206, and a P-type doped semiconductor layer 208. The N-type doped semiconductor layer 204, the light-emitting layer 206, and the P-type doped semiconductor layer 208 may sequentially be formed on the undoped semiconductor layer 202. In another words, the light-emitting layer 206 may be formed between N-type doped semiconductor layer 204 and the P-type doped semiconductor layer 208.

The LED 120 of the present disclosure is a GaN-based LED, for example. In such embodiments, the P-type doped semiconductor layer 208 is, for example, a P-type GaN layer (p-GaN), and the N-type doped semiconductor layer 204 is, for example, an N-type GaN layer (n-GaN). In addition, the light-emitting layer 206 is referred to as an active layer and a structure thereof is, for example, a multiple quantum well (MQW) formed by alternately stacking multiple InGaN layers and multiple GaN layers. The undoped semiconductor layer 242 is, for example, an undoped GaN layer (u-GaN).

The LED 120 can further include a protection layer 210 covering a surface and at least a portion of sidewall of the semiconductor stack 200. The protection layer 260 can provide functions of electrical insulation, protection and light reflection. The protection layer 260 may include silicon oxide, silicon nitride, or a stack of two materials with different refractive index, but the present disclosure is not limited to the above.

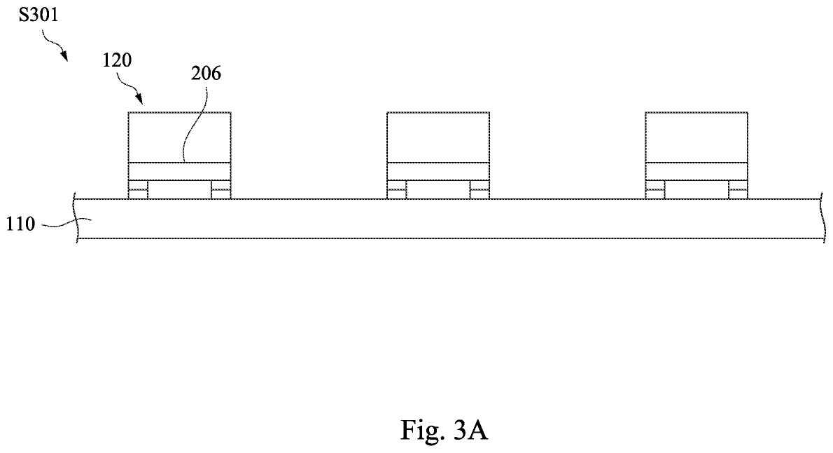

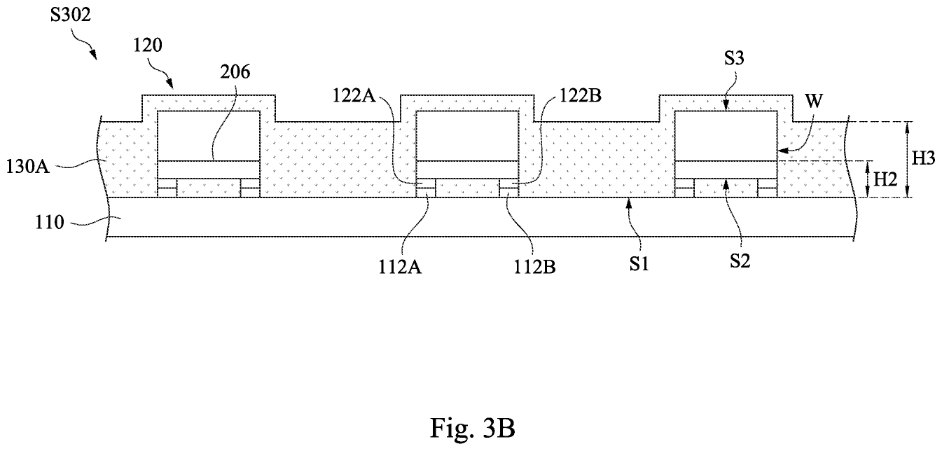

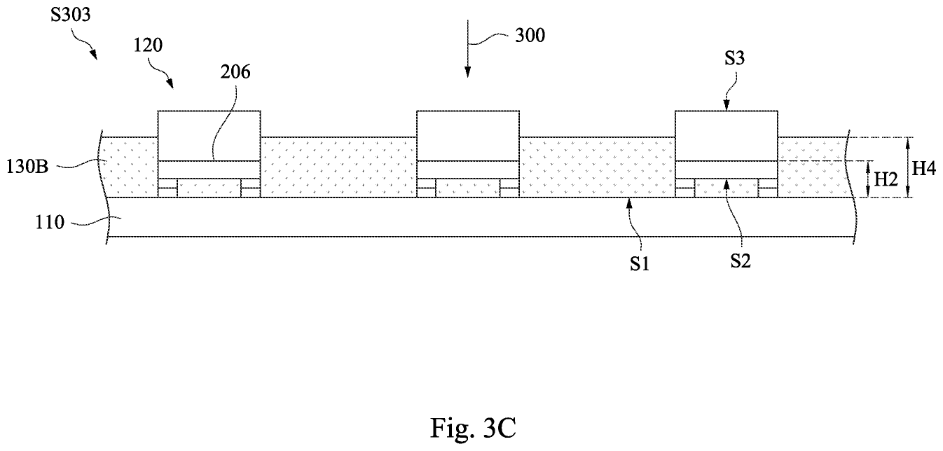

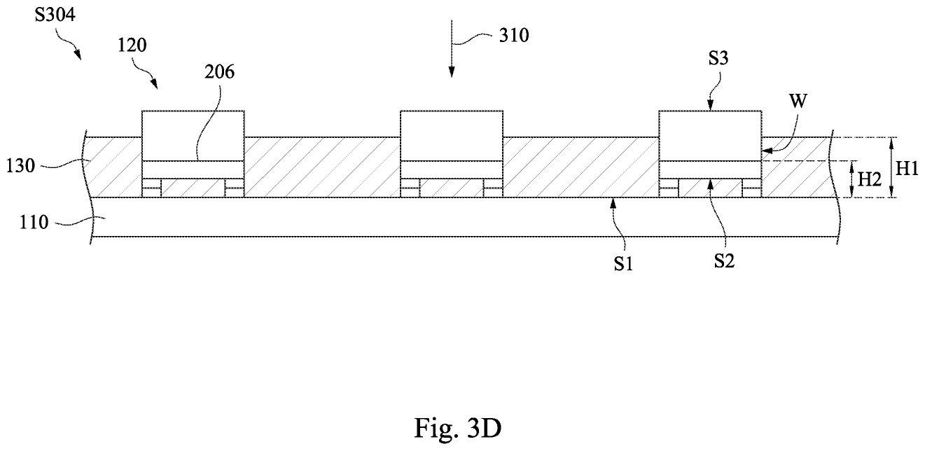

Returning to FIG. 1, it is noted that the LED 120 shown in FIG. 1 is simplified and no semiconductor stack 200 as shown in FIG. 2 is illustrated in FIG. 1. Rather, the LED 120 shown in FIG. 1 (also in the following FIG. 3A to FIG. 10) indicates an exemplary arrangement of the light-emitting layer 206.

As shown in FIG. 1, a light-reflecting resist 130 is disposed between the adjacent LEDs 120. A remaining room of a pitch P of the LED 120 excluded of the dimension of the single LED 120 is referred as available room for disposing the light-reflecting resist 130. The dimension of each LED 120 can be in micron scale, and in such embodiment the LED 120 can be referred to as a micro-LED. For example, the dimension of each LED 120 may be in a range between about 1 μm and about 100 μm. For a further example, the dimension of each LED 120 may be in a range between about 10 μm and about 50 μm. In some embodiments, the pitch P of the LED 120 can be less than about 100 μm.

The light-reflecting resist 130 can at least be disposed between the electrode 122A and the electrode 122B in addition to between the adjacent LEDs 120. In other words, the light-reflecting resist 130 surrounds the LED 120. In some embodiments, the light-reflecting resist 130 can directly contact the LED 120. For example, the light-reflecting resist 130 can directly contact a side surface W of the LED 120. In some other examples, the light-reflecting resist 130 can directly contact the second surface S2 of the LED 120.

The reflectance of the light-reflecting resist 130 can greater than about 60%. With the light-reflecting resist 130 that is able to reflect a light, when the LED 120 gives off the light outwards, the light-reflecting resist 130 surrounding the LED 120 can reflect and divert the light, thereby decreasing the light loss of the LED 120 or the light mixing among each LED 120. For example, the light-reflecting resist 130 disposed between the adjacent LEDs 120 can reflect the light coming from an inside of the LED 120 (i.e., the light-emitting layer 206) to the side surface W and can divert the light in a direction from the side surface W to the inside of the LED 120. In some other examples, the light-reflecting resist 130 disposed between the electrode 122A and the electrode 1228 can reflect the light coming from the inside of the LED 120 (i.e., the light-emitting layer 206) to the second surface S2, and can divert the light in a direction from the second surface S2 to the inside of the LED 120.

In some embodiments, a first height H1 of the light-reflecting resist 130 is higher than a second height H2 of the light-emitting layer 206. The first height H1 is measured from a top surface of the light-reflecting resist 130 to the first surface S1 of the substrate 110. The second height H2 is measured from a top surface of the light-emitting layer 206 to the first surface S1 of the substrate 110. When the first height H1 of the light-reflecting resist 130 is greater than the second height H2 of the light-emitting layer 206, the light-reflecting resist 130 can reflect the light coming from the light-emitting layer 206. On the other hand, when the first height H1 of the light-reflecting resist 130 is less than the second height H2 of the light-emitting layer 206, the light coming from the light-emitting layer 206 may directly move outwards and may not be reflected back to the inside of the LED 120 by the light-reflecting resist 130. Accordingly, the light-reflecting resist 130 may not perform the function of reflection, causing unacceptable light loss or light mixing. Consequently, the first height H1 of the light-reflecting resist 130 is at least greater than the second height H2 of the light-emitting layer 206, such that the light-reflecting resist 130 can effectively reflect the light coming from the light-emitting layer 206 of the LED 120.

In some further embodiments, the first height H1 of the light-reflecting resist 130 is greater than the second height H2 of the light-emitting layer 206. The light-reflecting resist 130 is entirely attached to a portion of the LED 120 below the first height H1. Therefore, the light-reflecting resist 130 can block the light-emitting layer 206, furthering decreasing light loss and light mixing. For example, the light-reflecting resist 130 can be entirely attached to the portion of the side surface W of the LED 120 below the first height H1. As a result, the light-reflecting resist 130 can cover the light-emitting layer 206 through the side surface W of the LED 120, thereby decreasing light loss or light mixing. In some other examples, the light-reflecting resist 130 can be entirely attached to the second surface S2 of the LED 120, thereby decreasing light loss or light mixing. In some embodiments, a lateral space among the second surface S2, the electrode 122A and the electrode 122B can be entirely filled with the light-reflecting resist 130. In some embodiments, a space among the second surface S2, the electrode 122A, the electrode 1228, the contact 112A, the contact 112B and the first surface S1 can be entirely filled with the light-reflecting resist 130.

An upper limit of the first height H1 of the light-reflecting resist 13 can be adjusted according to the design of the device. For example, when the first height H1 of the light-reflecting resist 130 is between the light-emitting layer 206 and a top surface of the LED 120 (e.g., a third surface S3 of the LED 120), a light-emitting angle of the LED 120 may be larger. In some embodiments, when the first height H1 of the light-reflecting resist 130 is level with or higher than the top surface of the LED 120 (e.g., the third surface S3 of the LED 120), a light-emitting angle of the LED 120 may be smaller (e.g., converged).

In some embodiments, the light-reflecting resist 130 causes the reflections of the light that undergo scattering (light scattering). In other words, the light-reflecting resist 130 causes a diffusion reflection. The light-reflecting resist 130 may include multiple scattering particles (not shown herein) in the light-reflecting resist 130. The material of the scattering particles may include titanium dioxide, zirconium dioxide, other suitable material, or a combination thereof. In some embodiments, the light scattering can be caused by the scattering particles in the light-reflecting resist 130.

Referring to FIG. 3A to FIG. 3D, FIG. 3A to FIG. 3D are cross-sectional views of the light emitting device 100 of FIG. 1 in various process stages in accordance with some embodiments. Unless otherwise illustrated, the order in which some or all of the operations are described should not be construed to imply that these operations are necessarily order dependent. Alternative ordering will be appreciated having the benefit of this description. Additional operations can be provided before, during, and/or after these operations, and may be briefly described herein. Further, it will be understood that not all operations are necessarily present in each embodiment provided herein. Also, it will be understood that not all operations are necessary in some embodiments.

Referring to FIG. 3A, FIG. 3A shows an operation 301 of disposing LED 120 on the substrate 110.

Referring to FIG. 3B, FIG. 3B shows an operation S302 of filling a space between the adjacent LEDs 120 and a space between the electrode 122A and the electrode 122B with a resist material 130A.

Particularly, the resist material 130A can directly contact the LED 120. For example, the resist material 130A can directly contact the side surface W of the LED 120. In some other examples, the resist material 130A can directly contact the second surface S2 of the LED 120. In some embodiments, a lateral space defined by the second surface S2, the electrode 122A and the electrode 122B can be entirely filled with the resist material 130A. In some embodiments, a space defined by the second surface S2, the electrode 122A, the electrode 122B, the contact 112A, the contact 112B and the first surface S1 can be entirely filled with the resist material 130A.

In some embodiments, a third height H3 of the resist material 130A is greater than the second height H2 of the light-emitting layer 206 of the LED 120 to allow the later-formed first height H1 of the light-reflecting resist 130 to be greater than the second height H2 of the light-emitting layer 206 of the LED 120 (referring to FIG. 1 or FIG. 3D).

The resist material 130A can include a liquid material. With fluidity of the liquid material, a gap between the LEDs 120 can be filled with the resist material 130, and each LED 120 can be surrounded by the resist material 130. The resist material 130A can further include multiple scattering particles (not shown herein) in the resist material 130A. In some embodiments, the scattering particles are blended with and uniformly distributed in the liquid material to form the resist material 130A.

In some embodiments, during adding the resist material 130A, the resist material 130A may be attached to the side surface W of the LED 120 and overlie an upper portion of the LED 120 along the side surface W. For example, the resist material 130A overlies a top surface (e.g., the third surface S3) of the LED 120, as shown in FIG. 3B. In some embodiments, after filling the space between the adjacent LEDs 120 and the space between the electrode 122A and the electrode 122B with the resist material 130A, performing a soft bake on the resist material 130A.

Referring to FIG. 3C, FIG. 3C shows an operation S303 of performing a lithography process 300 to remove a portion of the resist material 130A overlying the top surface (e.g., the third surface S3) of the LED 120. In some embodiments, the lithography process 300 can include disposing resist pattern (not shown herein) on the resist material 130A (referring to FIG. 3B), and then performing exposure and development process to remove a portion of the resist material 130A without the resist pattern covered. That is, the portion of the resist material 130A overlying the top surface (e.g., the third surface S3) of the LED 120 is removed.

After the lithography process 300, the resist material 130A is partially removed to form a resist material 130B. In FIG. 3C, since there is not resist material 130B overlying the top surface (e.g., the third surface S3) of the LED 120, the normal light emission of the LED 120 can be increased.

In some embodiments, a fourth height H4 of resist material 130B remains greater than the second height H2 of the light-emitting layer 206 of the LED 120 to allow the later-formed first height H1 of the light-reflecting resist 130 to be greater than the second height H2 of the light-emitting layer 206 of the LED 120 (referring to FIG. 1 or FIG. 3D).

Referring to FIG. 3D, FIG. 3D shows an operation S304 of performing a thermal treatment 310 to cure the resist material 130B and form the light-reflecting resist 130. The formed the light-reflecting resist 130 is substantially the same as described in FIG. 1, and therefore no further description is elaborated herein.

The thermal treatment 310 can be adjusted according to various types of resist material. In some embodiments, the temperature used in the thermal treatment 310 is between about 200° C. and about 250° C. In some embodiments, the duration of the thermal treatment 310 is between about 10 minutes and about 40 minutes.

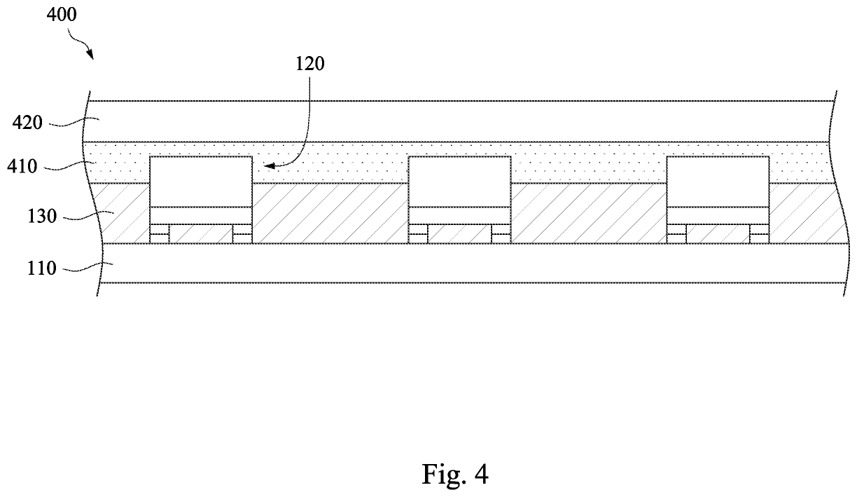

Referring to FIG. 4, FIG. 4 is a cross-sectional view of a light emitting device 400 in accordance with some other embodiments. The light emitting device 400 of FIG. 4 is basically similar to the light emitting device 100 of FIG. 1. In some embodiments as shown in FIG. 4, the light emitting device 400 includes the components shown in FIG. 1 (e.g., the substrate 110, the LED 120 and the light-reflecting resist 130), an adhesive layer 410 and a working piece 420. The adhesive layer 410 and the working piece 420 can be disposed on the LED 120 and the light-reflecting resist 130. The adhesive layer 410 may include an optical clear adhesive (OCA) and may be formed between the working piece 420 and the light-reflecting resist 130 by coating process.

The working piece 420 can be a single-layer or multi-layer structure. The working piece 420 can include a protection layer, a cover glass, an adhesive layer (e.g., OCA), polarizing layer, retardation plate, metal layer, any suitable members, or a combination thereof. For example, the polarizing layer may include a wire grid polarizer (WGP). Particularly, the WGP of the polarizing layer can be made up with multiple wires that are spaced away from and substantially parallel to each other. The WGP of the polarizing layer can allow light with a certain polarization (e.g., P polarization) transmitting through and allow light with another certain polarization (e.g., S polarization) reflected. The function of the working piece 420 can be adjusted according to the design and requirement of the device.

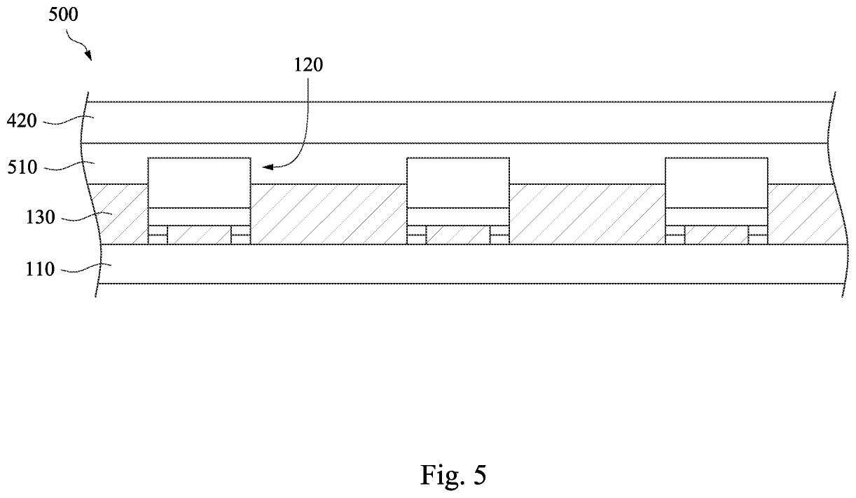

Referring to FIG. 5, FIG. 5 is a cross-sectional view of a light emitting device 500 in accordance with some other embodiments. The structure of FIG. 5 is similar to the structure of FIG. 4, and the difference is that the adhesive layer 410 in FIG. 4 is omitted in FIG. 5. Therefore, air 510 is present between the light-reflecting resist 130 and the working piece 420. In some embodiments as shown in FIG. 5, the light emitting device 500 includes the components shown in FIG. 1 (e.g., the substrate 110, the LED 120 and the light-reflecting resist 130), air 510 and the working piece 420. The working piece 420 is disposed on the LED 120 and the light-reflecting resist 130. Air 510 is between the light-reflecting resist 130 and the working piece 420.

It is noted that the structure in FIG. 5 can still include an adhesive layer (not shown herein). For example, the adhesive layer can only be disposed a periphery (not shown herein) of the light emitting device 500. Therefore, gas, e.g., air 510) can be present between the light-reflecting resist 130 and a central area of the working piece 420, as shown in FIG. 5. In other words, there substantially is an air bond on the light-reflecting resist 130.

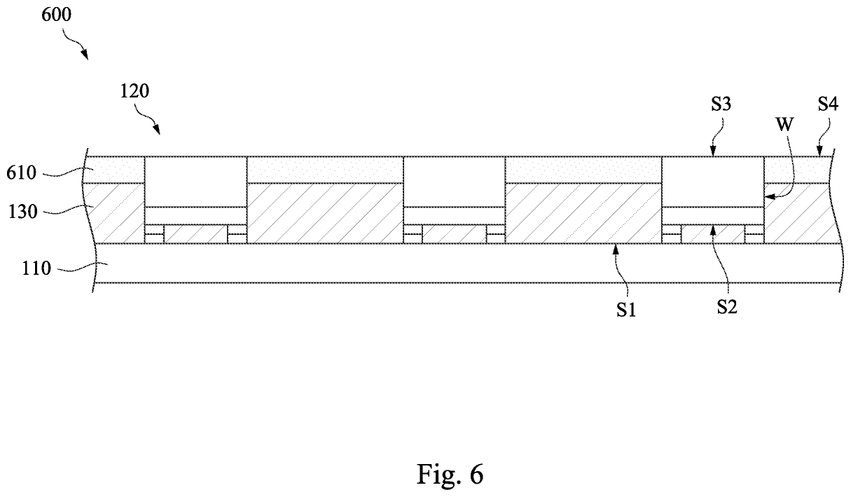

Referring to FIG. 6, FIG. 6 is a cross-sectional view of a light emitting device 600 in accordance with some other embodiments. The structure of FIG. 6 is similar to the structure of FIG. 4. In some embodiments as shown in FIG. 6, the light emitting device 600 includes the components shown in FIG. 1 (e.g., the substrate 110, the LED 120 and the light-reflecting resist 130) and a first optical function layer 610. The first optical function layer 610 is disposed on the LED 120 and the light-reflecting resist 130.

The first optical function layer 610 include a light-absorbing layer with light absorption rate more than about 90%. In some embodiments, the material of the light-absorbing layer can include molybdenum oxide, tantalum or a combination thereof to form a black material.

In a case where the first optical function layer 610 includes the light-absorbing layer, the first optical function layer 610 can be positioned between the adjacent LEDs 120 to space apart the LED 120. Further, in some embodiments, the first optical function layer 610 surrounds the LED 120. In addition, a top surface (e.g., a fourth surface S4) of the first optical function layer 610 can be level with or higher than the top surface (e.g., the third surface S3) of the LED 120 to avoid light mixing, thereby increasing the contrast performance of the device.

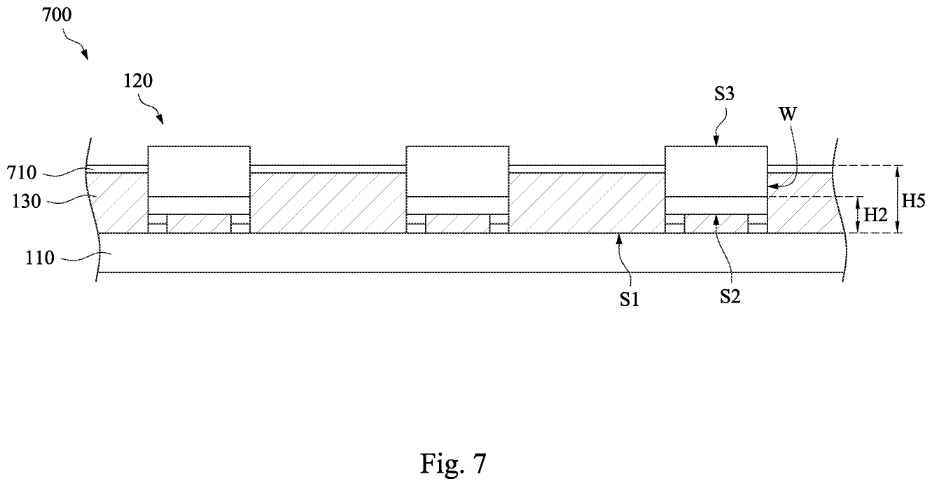

Referring to FIG. 7, FIG. 7 is a cross-sectional view of a light emitting device 700 in accordance with some other embodiments. The structure of FIG. 7 is similar to the structure of FIG. 6, and the difference is that a second optical function layer 710 is used in FIG. 7. The second optical function layer 710 can include a reflective layer to reflect light. The reflective layer can be a single-layer or multi-layer structure, and can include metal (e.g., titanium), alloy, or other suitable material capable of reflection. In some embodiments, the second optical function layer 710 reflects light in a way of specular reflection.

In a case where the second optical function layer 710 includes the reflective layer, the second optical function layer 710 is can be positioned between the adjacent LEDs 120 to space apart the LED 120. Further, in some embodiments, the second optical function layer 710 is disposed on the side surface W of the LED 120. In addition, the second optical function layer 710 and the light-reflecting resist 130 collectively have a fifth height H5. The fifth height H5 can be greater than the second height H2 of the light-emitting layer 206 of the LED 120, thereby increasing the efficiency of light emission.

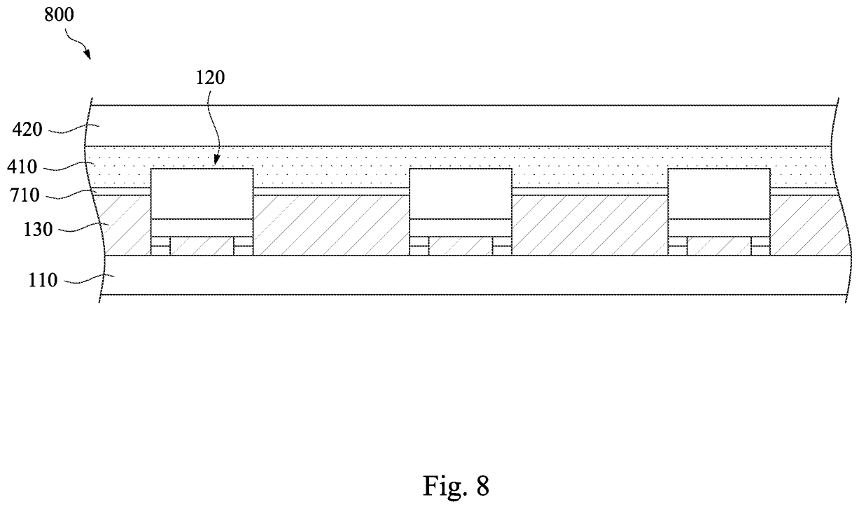

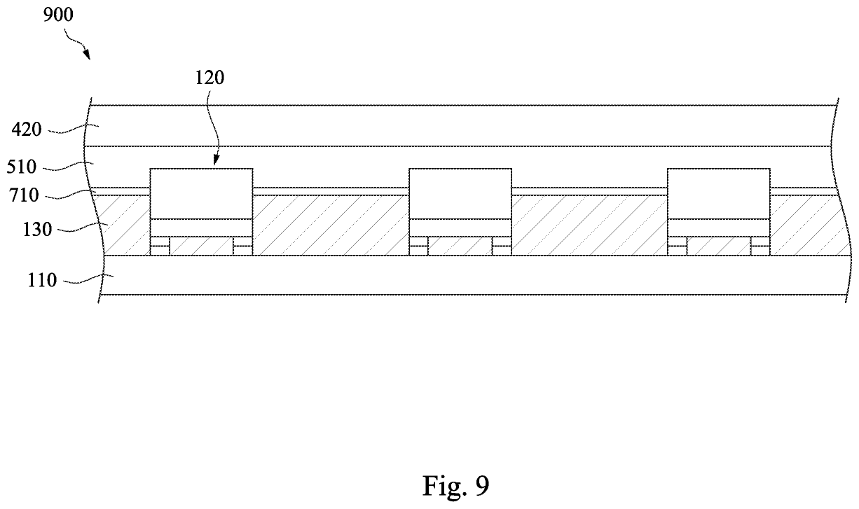

Referring to FIG. 8 and FIG. 9, FIG. 8 and FIG. 9 are respectively cross-sectional views of a light emitting device 800 and a light emitting device 900 in accordance with some other embodiments. In FIG. 8, the working piece 420, the adhesive layer 410 and the optical function layer (e.g., the second optical function layer 710 of the reflective layer in FIG. 7) can be disposed on the structure of FIG. 1 (e.g., on the substrate 110, LED 120 and the light-reflecting resist 130) to form the light emitting device 800. Similarly, in FIG. 9, the working piece 420 and the optical function layer (e.g., the second optical function layer 710 of the reflective layer in FIG. 7) can be disposed on the structure of FIG. 1 (e.g., on the substrate 110, LED 120 and the light-reflecting resist 130) to form the light emitting device 900 in a way of air bond. The light emitting device 800 and the light emitting device 900 are examples and the present disclosure is not limited thereto. An optical function layer and a working piece can be adjusted according to various design and requirement of device. In addition, an adhesive layer can be used or air bond can be implemented to form a light emitting device.

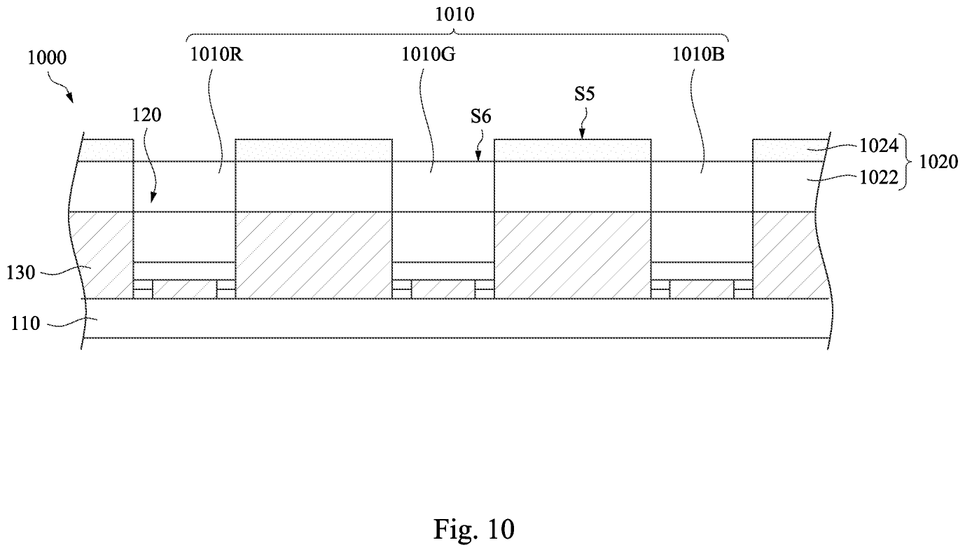

Referring to FIG. 10, FIG. 10 is a cross-sectional view of a light emitting device 1000 with a color conversion layer 1010 in accordance with some embodiments. The light emitting device 1000 includes the components shown in FIG. 1 (e.g., the substrate 110, the LED 120 and the light-reflecting resist 130), the color conversion layer 1010 and a third optical function layer 1020. The color conversion layer 1010 and the third optical function layer 1020 may be disposed on the light-reflecting resist 130 and the LED 120, and the color conversion layer 1010 may be positioned in the third optical function layer 1020. In some embodiments as shown in FIG. 10, the color conversion layer 1010 can include at least three color conversion units, such as a color conversion unit 1010R, a color conversion unit 1010G and a color conversion unit 1010B, but the present disclosure is not limited thereto. The color conversion unit 1010R, 1010G and 1010B can be corresponded to LED 120 one by one.

The color conversion unit 1010R, 1010G and 10108 can be a single-layer or multi-layer structure having photoluminescence (PL) material. The PL material can include phosphor material, quantum dot (QD) material, perovskite material, or other suitable material. In some embodiments, the color conversion unit 1010R, 1010G and 1010B can include scattering particles to moderate the properties (e.g., waveform) of light passing through the color conversion unit 1010R, 1010G or 1010B.

In some embodiments, the color conversion unit 1010R can include a QD material that emits red light, the color conversion unit 1010G can include a QD material that emits green light, and the color conversion unit 1010B can include a transparent resist or a transparent flat layer. The color conversion unit 1010B may not be doped with any QD material, but the present disclosure is not limited thereto. In some embodiments, the color conversion unit 1010B can include scattering particles. In some embodiments where the LED 120 emits blue light, the color conversion unit 1010R can transfer the wavelength of blue light into the wavelength of red light, the color conversion unit 1010G can transfer the wavelength of blue light into the wavelength of green light, and the light emitted from the LED 120 can directly pass through the color conversion unit 1010B. Thus, light passing though the color conversion unit 1010R, 1010G and 1010B can respectively be red light, green light and blue light. In some other embodiments, if the color conversion unit 1010B includes a QD material that emits red light, the LED 120 can emit ultraviolet (UV). In such embodiments, the other color conversion unit such as the color conversion unit 1010R or the color conversion unit 1010G can also transfer the wavelength of UV into the wavelength of corresponding light such as red light or green light.

The third optical function layer 1020 may include a barrier structure 1022. The barrier structure 1022 can be disposed between the adjacent color conversion unit 1010R, 1010G and 1010B to space apart each color conversion unit 1010R, 1010G and 1010B. In some embodiments, the barrier structure 1022 provide function of reflecting light or further scattering light, thereby increasing the efficiency of light emission. In some embodiments, the material of the barrier structure 1022 is substantially the same as the material of the light-reflecting resist 130.

In FIG. 10, the color conversion layer 1010 is disposed in the third optical function layer 1020. Particularly, the color conversion layer 1010 is disposed in the barrier structure 1022 of the third optical function layer 1020. In some embodiments, the color conversion layer 1010 disposed in the barrier structure 1022 of the third optical function layer 1020 can be formed by forming the color conversion layer 1010 on the corresponding LED 120, adding a barrier structure material (not shown herein), and curing the barrier structure material to become the barrier structure 1022. In some other embodiments, the color conversion layer 1010 disposed in the barrier structure 1022 of the third optical function layer 1020 can be formed by forming a barrier structure material (not shown herein) on the LED 120 and the light-reflecting resist 130, patterning the barrier structure material to form an opening (not shown herein) on the LED 120 and expose the LED 120, and then forming the color conversion layer 1010 in the opening.

The third optical function layer 1020 can further include a light-absorbing layer 1024 disposed on the barrier structure 1022. The light-absorbing layer 1024 is substantially the same as the light-absorbing layer described as the first optical function layer 610 in FIG. 6. A top surface (e.g., the fifth surface S5) of the light-absorbing layer 1024 can be level with or higher than a top surface (e.g., a sixth surface S6) of the color conversion layer 1010 to prevent light mixing, thereby increasing the contrast performance of the device.

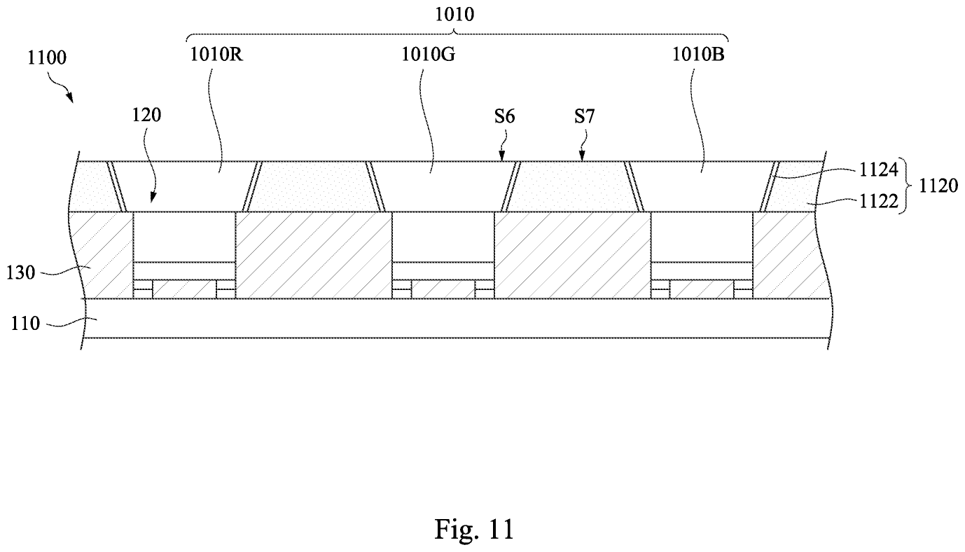

Referring to FIG. 11, FIG. 11 is a cross-sectional view of a light emitting device 1100 with the color conversion layer 1010 in accordance with some other embodiments. The light emitting device 1100 can include the components shown in FIG. 1 (e.g., the substrate 110, the LED 120 and the light-reflecting resist 130), the color conversion layer 1010 and a fourth optical function layer 1120. The color conversion layer 1010 and the fourth optical function layer 1120 may be spaced on the light-reflecting resist 130 and LED 120, and the color conversion layer 1010 is disposed in the fourth optical function layer 1120.

The fourth optical function layer 1120 can include a light-absorbing layer 1122 disposed on the light-reflecting resist 130. The light-absorbing layer 1122 is substantially the same as the light-absorbing layer described as the first optical function layer 610 in FIG. 6. A top surface (e.g., a seventh surface S7) of the light-absorbing layer 1122 can be level with or higher than the top surface (e.g., a sixth surface S6) of the color conversion layer 1010 to prevent light intended to direct to one color conversion unit (e.g., light is intended to direct to the color conversion unit 1010R) from moving to the other color conversion unit (e.g., light unintendedly moves to the color conversion unit 1010G or 1010B). Thus, the light-absorbing layer 1122 can avoid light mixing, thereby increasing the contrast performance of the device.

The fourth optical function layer 1120 can further include a reflective layer 1124 disposed on at least one sidewall of the color conversion unit 1010R, 1010G and 1010B. The reflective layer 1124 can prevent light (e.g., light emitted by the LED 120 and/or colorful light transferred by the color conversion units) directing to the sidewall of the color conversion unit 1010R, 1010G and 1010B from being absorbed by the light-absorbing layer 1122, thereby increasing the efficiency of light emission.

The present disclosure discloses various embodiments to provide a light emitting device with a light-reflecting resist and a method of fabricating the same. The light-reflecting resist is formed around and below the LED by filling a space between LEDs and a space between the LED and contacts with a light-reflecting resist material. When light emitted by the LED direct outwards, the light-reflecting resist around and below the LED can reflect the light back to an inside of the LED, thereby decreasing the light loss and light mixing. Therefore, the efficiency of light emission can be boosted.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light emitting device, comprising:
a substrate;
a plurality of light emitting diodes, disposed on the substrate and comprising a first electrode and a second electrode, wherein the first electrode and the second electrode are disposed on a first surface of the plurality of light emitting diodes and the first surface is faced towards the substrate; and
a light-reflecting resist, disposed between the plurality of light emitting diodes and directly contacting a side surface of the plurality of light emitting diodes, wherein at least a portion of the light-reflecting resist are disposed between the first electrode and the second electrode.

2. The light emitting device of claim 1, wherein the light-reflecting resist directly contacts the first surface of the plurality of light emitting diodes.

3. The light emitting device of claim 1, wherein the light-reflecting resist has a first height, and the light-reflecting resist is entirely attached to a portion of the side surface below the first height.

4. The light emitting device of claim 3, wherein the light-reflecting resist is entirely attached to the first surface.

5. The light emitting device of claim 3, wherein the plurality of light emitting diodes comprises a light-emitting layer, and the light-emitting layer has a second height lower than the first height.

6. The light emitting device of claim 5, further comprising an optical function layer disposed on the light-reflecting resist.

7. The light emitting device of claim 6, wherein the optical function layer comprises a light-absorbing layer, and a top surface of the light-absorbing layer is higher than or level with a top surface of the plurality of light emitting diodes.

8. The light emitting device of claim 6, wherein the optical function layer comprises a reflective layer, and the light-reflecting resist and the reflective layer collective have a third height higher than the second height of the light-emitting layer.

9. The light emitting device of claim 6, wherein the optical function layer comprises a barrier structure, and a top surface of the barrier structure is higher than a top surface of the plurality of light emitting diodes.

10. The light emitting device of claim 6, further comprising a color conversion layer disposed in the optical function layer and on the plurality of light emitting diodes.

11. The light emitting device of claim 1, wherein a reflectance of the light-reflecting resist is greater than 60%.

12. The light emitting device of claim 1, wherein the light-reflecting resist comprises a plurality of scattering particles.

13. The light emitting device of claim 1, wherein the light-reflecting resist cause a diffusion reflection.

14. The light emitting device of claim 1, further comprising a working piece disposed on the light-reflecting resist, and air is present between the light-reflecting resist and the working piece.

15. A method of fabricating a light emitting device, comprising:
disposing a plurality of light emitting diodes on a substrate, wherein each light emitting diode of the plurality of light emitting diodes comprises a first electrode and a second electrode; and
after disposing the plurality of light emitting diodes on the substrate, disposing a resist material between adjacent light emitting diodes of the plurality of light emitting diodes and between the first electrode and the second electrode, wherein the resist material directly contacts a side surface of the plurality of light emitting diodes.

16. The method of fabricating the light emitting device of claim 15, wherein disposing the resist material between the first electrode and the second electrode comprises entirely filling a space between the first electrode and the second electrode with the resist material.

17. The method of fabricating the light emitting device of claim 15, wherein disposing the resist material between adjacent light emitting diodes of the plurality of light emitting diodes comprises making a height of the resist material higher than a height of a light-emitting layer of the plurality of light emitting diodes.

18. The method of fabricating the light emitting device of claim 15, wherein the resist material comprises a plurality of scattering particles distributed within the resist material.

19. The method of fabricating the light emitting device of claim 15, further comprising:
removing a portion of the resist material by performing a lithography process, wherein the portion of the resist material is on a top surface of the plurality of light emitting diodes.

20. The method of fabricating the light emitting device of claim 15, further comprising:
curing the resist material by performing a thermal treatment to form a light-reflecting resist.
